(19) United States
(12) Patent Application Publication
(10) Pub. No.: US 2016/0356824 A1
(43) Pub. Date: Dec. 8, 2016

(54) LOSS-PHASE LACK-VOLTAGE DETECTION CIRCUIT FOR THREE-PHASE INPUT POWER

(71) Applicant: HIWIN MIKROSYSTEM CORP., Taichung City (TW)

(72) Inventors: Chang-Huan WU, Taichung City (TW); Wei-Cheng WANG, Taichung City (TW); Chi-Yin LO, Taichung City (TW)

(21) Appl. No.: 14/732,714

(22) Filed: Jun. 6, 2015

(51) Int. Cl. G01R 19/00; G01R 19/22

(52) U.S. Cl. CPC G01R 19/0084; G01R 19/22

(57) ABSTRACT

A loss-phase lack-voltage detection circuit for three-phase input power includes a half-wave rectifier circuit, a bleeder circuit, an optical coupler circuit and a digital signal processor sequentially connected with each other. The half-wave rectifier circuit serves to rectify the input power. The bleeder circuit has multiple bleeder resistors for stepping down the voltage. The optical coupler circuit serves to generate judgment signal in form of pulse wave. The digital signal processor serves to calculate the duration for which the pulse wave stays at the peak value to judge the loss-phase state of the input power.

### BACKGROUND OF THE INVENTION

1. Field of the Invention

The present invention relates generally to a circuit structure, and more particularly to a loss-phase lack-voltage detection circuit for three-phase input power.

2. Description of the Related Art

It is known that an electronic apparatus needs an external power supply for operation. It often takes place that the external power supply is unstable. For example, the external power supply often has the problems of unstable voltage or loss-phase state of three-phase power. This will affect or even damage the electronic apparatus. Therefore, some conventional detection circuits for loss-phase and lack-voltage protection have been developed.

For example, Chinese Patent No. CN100403616 discloses a first loss-phase and lack-voltage detection device. The detection circuit samples the voltage and frequency of the input power after filtered. The sampled value is compared with judgment value so as to judge whether there is a loss-phase problem. Chinese Patent No. CN102419400 discloses a second loss-phase and lack-voltage detection device. The detection device continuously samples the voltage of the input power seven times after filtered and compares the sampled values with each other to obtain the voltage difference for finding whether there is a loss-phase problem. The above two detection and sampling processes are quite complicated.

Chinese Patent No. CN202710671 and Chinese Patent No. CN203490298 respectively disclose a third loss-phase and lack-voltage detection device and a fourth loss-phase and lack-voltage detection device. These detection devices employ three sets of optical coupler circuits to judge whether the input power is in the loss-phase state. The cost for such detection devices is relatively high. Chinese Patent No. CN202111457 and Chinese Patent No. CN203491679 respectively disclose a fifth loss-phase and lack-voltage detection device and a sixth loss-phase and lack-voltage detection device. These detection devices employ six rectifier diodes and a high-voltage electrolytic capacitor for detecting the loss-phase state. The cost for such detection devices is relatively high. Also, the lifetime of the electrolytic capacitor is an important and considerable factor of the cost.

In addition, Patent No. CN203589705 and Chinese Patent No. CN101799520 respectively disclose two loss-phase detection devices. These loss-phase detection devices can only judge whether the input power in a loss-phase state, while lacking lack-voltage detection function.

Moreover, Patent No. CN203589705 discloses a modularized loss-phase detection circuit including a voltage step-down rectifier circuit, a loss-phase identification circuit, a lack-voltage protection circuit and a relay driving/controlling circuit for achieving protection effect. However, such detection circuit needs to utilize a relay protection system and has the shortcoming of too large volume.

### SUMMARY OF THE INVENTION

It is therefore a primary object of the present invention to provide a loss-phase lack-voltage detection circuit for three-phase input power. The loss-phase lack-voltage detection circuit includes rectifier diodes for rectifying the three-phase input power and multiple bleeder resistors for stepping down the voltage. The loss-phase lack-voltage detection circuit further includes an optical coupler circuit for generating judgment signal for a digital signal processor to judge the loss-phase and lack-voltage state of the input power. The loss-phase lack-voltage detection circuit is able to protect an electronic apparatus from being damaged due to unstable power supply.

To achieve the above and other objects, the loss-phase lack-voltage detection circuit for three-phase input power of the present invention includes:
a half-wave rectifier circuit having three rectifier diodes;
a bleeder circuit connected behind the half-wave rectifier circuit for judging voltage of the input power;
an optical coupler circuit having two optical coupler detection units, the optical coupler circuit being connected behind the bleeder circuit for generating judgment signal in form of pulse wave; and
a digital signal processor connected behind the optical coupler circuit for receiving the judgment signal and judging the loss-phase state of the input power by means of calculating the duration for which the pulse wave stays at the peak value.

The present invention can be best understood through the following description and accompanying drawings, wherein:

### BRIEF DESCRIPTION OF THE DRAWINGS

FIG. 1 is a circuit diagram of the present invention;

FIG. 2 is a flow chart of the loss-phase detection process of the present invention;

FIG. 3 is a circuit diagram of a second embodiment of the present invention; and

FIG. 4 is a flow chart of the loss-phase detection process of the second embodiment of the present invention.

### DETAILED DESCRIPTION OF THE PREFERRED EMBODIMENTS

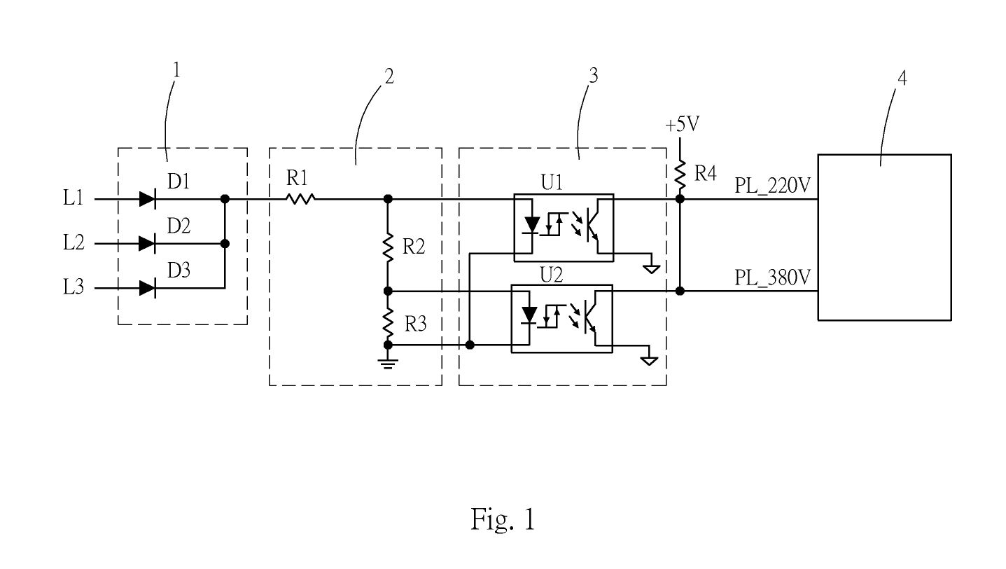

Please refer to FIG. 1. According to a first embodiment, the loss-phase lack-voltage detection circuit for three-phase input power of the present invention includes a half-wave rectifier circuit 1, a bleeder circuit 2, an optical coupler circuit 3 and a digital signal processor 4.

The half-wave rectifier circuit 1 has three rectifier diodes D1, D2, D3. After three-phase currents L1, L2, L3 are input, the rectifier diodes D1, D2, D3 serve to rectify the currents into half-wave form to output. The bleeder circuit 2 is connected behind the half-wave rectifier circuit 1 and is composed of three bleeder resistors R1, R2, R3. After rectified, the input power is stepped down by the bleeder resistors R1, R2, R3 to judge the voltage value.

The optical coupler circuit 3 is connected behind the bleeder circuit 2. The optical coupler circuit 3 has two optical coupler detection units U1, U2 for generating judgment signal in form of pulse wave. The digital signal processor 4 is connected behind the optical coupler circuit 3 for receiving the judgment signal and judging the loss-phase state of the input power by means of calculating the duration for which the pulse wave stays at the peak value.

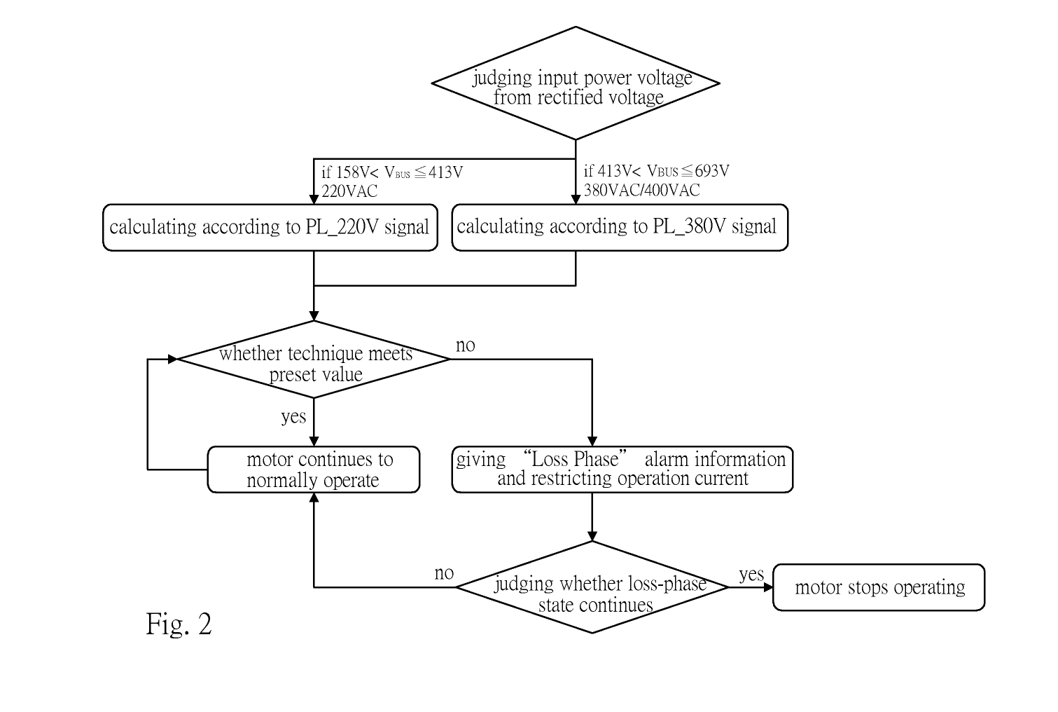

Please now refer to FIG. 2, which is a flow chart of the loss-phase detection process of the present invention. After the three-phase power is rectified, the bleeder circuit 2 judges the voltage value of the rectified power. In case the voltage of the rectified power falls within 158˜413V, the bleeder circuit 2 judges the power to be 220VAC. In case the voltage of the rectified power falls within 413V˜693V, the bleeder circuit 2 judges the power to be 380VAC.

Then, after the voltage of the input power is identified, according to the judged voltage classification, the power is input to the optical coupler detection units U1, U2 of the optical coupler circuit 3 to output judgment signal in the form of pulse wave. After the judgment signal is input to the digital signal processor 4, the digital signal processor 4 calculates the duration for which the pulse wave stays at the peak value and compares the duration with the inbuilt standard value so as to detect whether the input power is in loss of phase. With 220VAC/60 Hz input power taken as an example, in case the peak value duration of the pulse wave is 1.6 milliseconds, it is judged to be not in loss of phase. In case there are two peak value durations (1.6 milliseconds and 7.2 milliseconds) of the pulse wave, it is judged to be in loss of one phase. In case the peak value duration of the pulse wave is 12.7 milliseconds, it is judged to be in loss of two phases. In case the pulse wave continuously stays at the peak value, it is judged to be in loss of three phases.

In the case the detection result is that the input power is not free from loss-phase state, the system will give loss-phase alarm information and restrict the operation current until the state is improved. In the case the loss-phase state of the input power continues for a duration exceeding the preset value, the motor will stop operating to avoid damage.

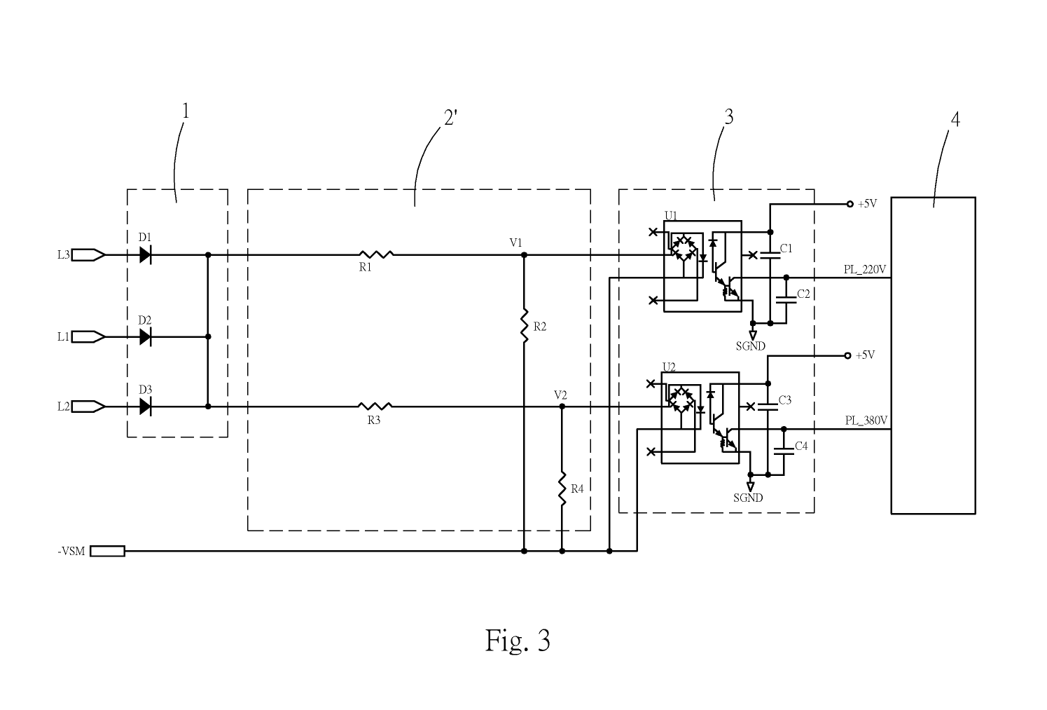

FIG. 3 shows a second embodiment of the present invention. The second embodiment is different from the first embodiment in the circuit composition of the bleeder circuit 2′. In this embodiment, the bleeder circuit 2′ is connected between the half-wave rectifier circuit 1 and the optical coupler circuit 3 and is composed of eight resistors R1 to R8 connected with each other. After the three-phase current is input and rectified, the bleeder circuit 2′ judges the voltage value. Then, according to the judged voltage value, the corresponding optical coupler detection units U1, U2 of the optical coupler circuit 3 is selectively driven to output the judgment signal in the form of pulse wave to the digital signal processor 4 so as to judge the loss-phase state of the current.

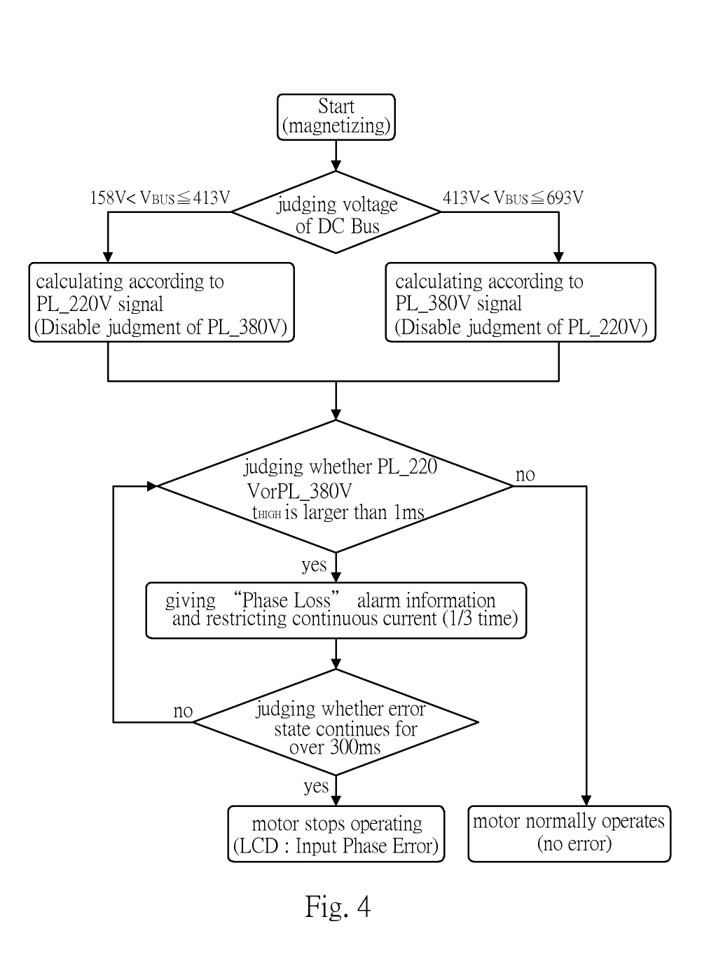

Please now refer to FIG. 4, which is a flow chart of the detection process of the second embodiment of the present invention. In this embodiment, after the three-phase power is rectified, the bleeder circuit 2 judges the voltage value of the rectified power. In case the voltage of the rectified power falls within 158˜413V, the voltage value is judged to be 220VAC. In case the voltage of the rectified power falls within 413V˜693V, the voltage value is judged to be 380VAC. Then, the digital signal processor 4 calculates the duration during which the pulse wave stays at the peak value and compares the duration with the inbuilt standard value so as to detect whether the input power is in loss of phase.

According to the above arrangement, the present invention employs simple passive components and optical coupler circuit to provide loss-phase and lack-voltage detection function for the input power. The number of the components of the present invention is less and the cost of the present invention is lower.

The above embodiments are only used to illustrate the present invention, not intended to limit the scope thereof. Many modifications of the above embodiments can be made without departing from the spirit of the present invention.

What is claimed is:

1. A loss-phase lack-voltage detection circuit for three-phase input power comprising:
a half-wave rectifier circuit having three rectifier diodes;
a bleeder circuit connected behind the half-wave rectifier circuit for judging voltage of the input power;
an optical coupler circuit having two optical coupler detection units, the optical coupler circuit being connected behind the bleeder circuit for generating judgment signal in form of pulse wave; and
a digital signal processor connected behind the optical coupler circuit for receiving the judgment signal and judging the loss-phase state of the input power by means of calculating the duration for which the pulse wave stays at the peak value.

2. The loss-phase lack-voltage detection circuit for three-phase input power as claimed in claim 1, wherein the bleeder circuit and the optical coupler detection units serve to detect two sets of input power, in case the voltage of the input power falls within 158˜413V, the bleeder circuit judging the input power to be 220VAC, in case the voltage of the input power falls within 413V˜693V, the bleeder circuit judging the input power to be 380VAC.
